(19) United States
(12) Patent Application Publication
(10) Pub. No.: US 2026/0055503 A1
(43) Pub. Date: Feb. 26, 2026

(54) COMPOSITIONS, METHODS, AND DEVICES

(71) Applicant: OHIO STATE INNOVATION FOUNDATION, Columbus, OH (US)

(72) Inventors: Hongping ZHAO, Dublin, OH (US); A F M Anhar Uddin BHUYAN, Columbus, OH (US); Lingyu MENG, Columbus, OH (US)

(21) Appl. No.: 19/103,664

(22) PCT Filed: Aug. 17, 2023
(86) PCT No.: PCT/US23/30446

§ 371 Date: Feb. 13, 2025

Related U.S. Application Data
(60) Provisional application No. 63/398,959, filed on Aug. 18, 2022.

(51) Int. Cl. C23C 16/40; C09D 1/00

(52) U.S. Cl. CPC C23C 16/40; C09D 1/00

(57) ABSTRACT

Disclosed herein are compositions, methods, and devices. Disclosed herein is a composition comprising a β-(AlₓGa₁₋ₓ)₂O₃, having an x value of less than about 5% and comprising at least one n-carrier dopant. Also disclosed are methods of making the same. Also disclosed are devices comprising the disclosed compositions.

### CROSS-REFERENCE TO RELATED APPLICATIONS

This application claims the benefit of U.S. Provisional Application No. 63/398,959, filed Aug. 18, 2022, the content of which is incorporated herein by reference in its entirety.

### STATEMENT OF GOVERNMENT SUPPORT

This invention was made with government support under grant/contract number FA9550-18-1-0479, awarded by the Air Force Office of Scientific Research. The government has certain rights in the invention.

### BACKGROUND

Current semiconductor materials used in power devices are reaching their performance limits.

Thus compositions and devices with improved properties are needed. The compositions, methods, and devices discussed herein address these and other needs.

### SUMMARY

In accordance with the purposes of the disclosed compositions, methods, and devices as embodied and broadly described herein, the disclosed subject matter relates to compositions and devices and methods of making and use thereof.

In some aspects disclosed herein is a composition comprising a β-(AlₓGa₁₋ₓ)₂O₃, having an x value of less than about 5% and comprising at least one n-carrier dopant.

In still further aspects, the composition comprises the at least one n-carrier dopant in a concentration of about 1×10¹⁴ cm⁻³ to about 5×10¹⁷ cm⁻³.

In yet still further aspects, the disclosed herein composition is present as a substantially smooth thin film. Yet, in still further aspects, such a film has a thickness greater than about 2 μm.

Also disclosed herein is a method of making any of the disclosed herein compositions. In certain aspects, disclosed is a method of forming an Al-Ga-containing film comprising: (a) exposing a β-Ga₂O₃-based substrate to an aluminum precursor, a gallium precursor, and/or oxygen precursor at a first temperature and a first pressure; and (b) growing a β-(AlₓGa₁₋ₓ)₂O₃ thin film, wherein an x value is less than about 5%, at a growth rate greater than about 3 μm/h.

In yet still further aspects, the method of forming the Al-Ga-containing film comprises metal-organic chemical vapor deposition (MOCVD), molecular-beam epitaxy (MBE), hydride vapor phase epitaxy (HVPE), pulsed laser deposition (PLD), low-pressure chemical vapor deposition (LPCVD), or a combination thereof.

Also disclosed is a device comprising any of the disclosed herein compositions.

Additional advantages of the disclosed compositions, devices, and methods will be set forth in part in the description which follows and in part will be obvious from the description. The advantages of the disclosed compositions, devices, and methods will be realized and attained by means of the elements and combinations particularly pointed out in the appended claims. It is to be understood that both the foregoing general description and the following detailed description are exemplary and explanatory only and are not restrictive of the disclosed devices and methods, as claimed.

The details of one or more embodiments of the invention are set forth in the accompanying drawings and the description below. Other features, objects, and advantages of the invention will be apparent from the description and drawings, and from the claims.

### BRIEF DESCRIPTION OF THE FIGURES

The accompanying figures, which are incorporated in and constitute a part of this specification, illustrate several aspects of the disclosure and, together with the description, serve to explain the principles of the disclosure.

FIG. 1 shows an XRD ω-2θ scan profiles of β-(AlₓGa₁₋ₓ)₂O₃ films grown on (010) β-Ga₂O₃ substrates with various Al compositions. XRD peaks corresponding to 0.7%, 1.3%, and 2.0% of Al compositions were identified.

FIGS. 2A-2D shows a surface view FESEM images of β-(AlₓGa₁₋ₓ)₂O₃ films grown on (010) β-Ga₂O₃ substrates with (a) x=0%, (b) x=0.7%, (c) x=1.3%, and (d) x=2.0%, respectively.

FIG. 3 shows room temperature Hall mobility of β-(AlₓGa₁₋ₓ)₂O₃ films with x=0%-2% grown with different electron carrier concentrations.

FIG. 4 shows a schematic of a cross-sectional view of an (AlₓGa₁₋ₓ)₂O₃ Schottky barrier diode structure grown using a thick β-(AlₓGa₁₋ₓ)₂O₃ drift layer in accordance with one aspect.

FIG. 5 shows a general design of β-(AlₓGa₁₋ₓ)₂O₃ Schottky barrier diode with a graded Al content β-(AlₓGa₁₋ₓ)₂O₃ cap layer grown on top of thick low-Al content β-(AlₓGa₁₋ₓ)₂O₃ drift layer in accordance with one aspect for boosting device performance with high power figure-of-merit (P-FOM).

FIG. 6 shows a general design of β-(AlₓGa₁₋ₓ)₂O₃ PN heterojunction power diodes grown using thick β-(AlₓGa₁₋ₓ)₂O₃ as an n-type drift layer in accordance with one aspect.

FIG. 7 shows a schematic of a cross-sectional view of an (AlₓGa₁₋ₓ)₂O₃ Schottky barrier diode structure grown using a thick β-(AlₓGa₁₋ₓ)₂O₃ drift layer on a lattice-matched substrate in accordance with one aspect.

FIG. 8 shows a general design of β-(AlₓGa₁₋ₓ)₂O₃ Schottky barrier diode with a graded Al content β-(AlₓGa₁₋ₓ)₂O₃ cap layer grown on top of thick low-Al content β-(AlₓGa₁₋ₓ)₂O₃ drift layer on a lattice-matched substrate in accordance with one aspect for boosting device performance with high power figure-of-merit (P-FOM).

FIG. 9 shows a general design of β-(AlₓGa₁₋ₓ)₂O₃ PN heterojunction power diodes grown using thick β-(AlₓGa₁₋ₓ)₂O₃ as an n-type drift layer on a lattice-matched substrate in accordance with one aspect.

### DETAILED DESCRIPTION

The compositions, methods, and devices described herein may be understood more readily by reference to the following detailed description of specific aspects of the disclosed subject matter and the Examples included therein.

Before the present compositions, methods, and devices are disclosed and described, it is to be understood that the aspects described below are not limited to specific synthetic methods or specific reagents, as such may vary. It is also to be understood that the terminology used herein is for the purpose of describing particular aspects only and is not intended to be limiting.

Also, throughout this specification, various publications are referenced. The disclosures of these publications in their entirety are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

In this specification and in the claims that follow, reference will be made to a number of terms, which shall be defined to have the following meanings.

Throughout the description and claims of this specification, the word “comprise” and other forms of the word, such as “comprising” and “comprises,” means including but not limited to, and is not intended to exclude, for example, other additives, components, integers, or steps. As used in the specification and in the claims, the term “comprising” can include the aspects “consisting of” and “consisting essentially of.”

As used in the description and the appended claims, the singular forms “a,” “an,”and “the”include plural referents unless the context clearly dictates otherwise. Thus, for example, a reference to “a composition” includes mixtures of two or more such compositions, a reference to “an agent” includes mixtures of two or more such agents, reference to “the component” includes mixtures of two or more such components, and the like.

“Optional” or “optionally” means that the subsequently described event or circumstance can or cannot occur and that the description includes instances where the event or circumstance occurs and instances where it does not.

For the terms “for example” and “such as” and grammatical equivalences thereof, the phrase “and without limitation” is understood to follow unless explicitly stated otherwise.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in their respective testing measurements. Furthermore, when numerical ranges of varying scope are set forth herein, it is contemplated that any combination of these values, inclusive of the recited values, may be used. Further, ranges can be expressed herein as from “about” one particular value and/or to “about” another particular value. When such a range is expressed, another aspect includes from the one particular value and/or to the other particular value.

Similarly, when values are expressed as approximations, by use of the antecedent “about,” it will be understood that the particular value forms another aspect. It will be further understood that the endpoints of each of the ranges are significant both in relation to the other endpoint and independently of the other endpoint. Unless stated otherwise, the term “about” means within 5% (e.g., within 2% or 1%) of the particular value modified by the term “about.”

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6, etc., as well as individual numbers within that range, for example, 1, 2, 2.7, 3, 4, 5, 5.3, 6 and any whole and partial increments therebetween. This applies regardless of the breadth of the range.

Values can be expressed herein as an “average” value. “Average” generally refers to the statistical mean value.

As used herein, the term “composition” is intended to encompass a product comprising the specified ingredients in the specified amounts, as well as any product which results, directly or indirectly, from a combination of the specified ingredients in the specified amounts. In yet further aspects, and as described herein, the term “composition” can also refer to a product whose exact components are known and are determined by the methods disclosed herein.

As used herein, the term “substantially,” in, for example, the context “substantially no change,” refers to a phenomenon or an event that exhibits less than about 1% change, e.g., less than about 0.5%, less than about 0.1%, less than about 0.05%, or less than about 0.01% change. For example, when the term substantially no change is used in the context of substantially no change is observed in the oscillations of the molten electrolyte, it is understood that the change in the oscillations is less than about 1%, less than about 0.5%, less than about 0.1%, less than about 0.05%, or less than about 0.01%.

As used herein, the term “substantially,” in, for example, the context “substantially identical” or “substantially similar,” refers to a method or a system, or a component that is at least about 80%, at least about 85%, at least about 90%, at least about 91%, at least about 92%, at least about 93%, at least about 94%, at least about 95%, at least about 96%, at least about 97%, at least about 98%, at least about 99%, or about 100% by similar to the method, system, or the component it is compared to. Yet “substantially”can mean within 5%, e.g., within 4%, 3%, 2%, or 1%.

“Exemplary” means “an example of” and is not intended to convey an indication of a preferred or ideal embodiment. “Such as” is not used in a restrictive sense, but for explanatory purposes.

It is understood that throughout this specification, the identifiers “first” and “second” are used solely to aid in distinguishing the various components and steps of the disclosed subject matter. The identifiers “first” and “second” are not intended to imply any particular order, amount, preference, or importance to the components or steps modified by these terms.

References in the specification and concluding claims to parts by weight of a particular element or component in a composition denotes the weight relationship between the element or component and any other elements or components in the composition or article for which a part by weight is expressed. Thus, in a compound containing 2 parts by weight of component X and 5 parts by weight of component Y, X and Y are present at a weight ratio of 2:5 and are present in such ratio regardless of whether additional components are contained in the compound.

A weight percent (wt. %) of a component, unless specifically stated to the contrary, is based on the total weight of the formulation or composition in which the component is included. In certain aspects, the percentage is shown in atomic % as is measured based on the total number of atoms present in the composition.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that, typically, there is no limit on the number of items or terms in any combination, unless otherwise apparent from the context.

In certain aspects disclosed herein are compositions comprising a β-(AlₓGa₁₋ₓ)₂O₃, having an x value of less than about 5%. In still further aspects, the composition can further comprise at least one n-carrier dopant. In further aspects, Al can be present in the β-(AlₓGa₁₋ₓ)₂O₃ containing composition in small amounts. In such aspects, the x value that describes an amount of Al can be less than about 5%, less than about 4.5%, less than about 4%, less than about 3.5%, less than about 3%, less than about 2.5%, less than about 2%, less than about 1.5%, less than about 1%, less than about 0.5%, less than about 0.2%, or less than about 0.1%. In yet still further aspects, the x value can be from less than about 5% to greater than 0%, including exemplary values of about 4.9%, about 4.5%, about 4.2%, about 4%, about 3.8%, about 3.5%, about 3.2%, about 3%, about 2.8%, about 2.5%, about 2.2%, about 2%, about 1.8%, about 1.5%, about 1.2%, about 1%, about 0.9%, about 0.8%, about 0.7%, about 0.6%, about 0.5%, about 0.4%, about 0.3%, about 0.1%, about 0.1%, about 0.08%, about 0.05%, and about 0.01%.

Any known in the art n-carrier dopants can be present in the composition. In some aspects, the n-carrier dopant can comprise Si. Yet, in other aspects, additional n-carrier dopants can comprise Ge, Sn, or any combination thereof. In still further aspects, the concentration of the n-carrier dopant can be tunable.

In some examples, the n-carrier dopant is present in the composition at a concentration of about 1×10¹⁴ cm⁻³ to about 5×10¹⁷ cm⁻³, including exemplary values of about 2×10¹⁴ cm⁻³, about 3×10¹⁴ cm⁻³, about 4×10¹⁴ cm⁻³, about 5×10¹⁴ cm⁻³, about 6×10¹⁴ cm⁻³, about 7×10¹⁴ cm⁻³, about 8×10¹⁴ cm⁻³, about 9×10¹⁴ cm⁻³, about 1×10¹⁵ cm⁻³, about 2×10¹⁵ cm⁻³, about 3×10¹⁵ cm⁻³, about 4×10¹⁵ cm⁻³, about 5×10¹⁵ cm⁻³, about 6×10¹⁵ cm⁻³, about 7×10¹⁵ cm⁻³, about 8×10¹⁵ cm⁻³, about 9×10¹⁵ cm⁻³, about 1×10¹⁶ cm⁻³, 2×10¹⁶ cm⁻³, about 3×10¹⁶ cm⁻³, about, 4×10¹⁶ cm⁻³, about 5×10¹⁶ cm⁻³, about 6×10¹⁶ cm⁻³, about 7×10¹⁶ cm⁻³, about 8×10¹⁶ cm⁻³, about 9×10¹⁶ cm⁻³, about 1×10¹⁷ cm⁻³, 2×10¹⁷ cm⁻³, about 3×10¹⁷ cm⁻³, and 4×10¹⁷ cm⁻³. In still further aspects, the n-carrier dopant is present in the composition at a concentration greater than about 5×10¹⁷ cm⁻³, for example, about 1×10¹⁸ cm⁻³, about 1×10¹⁹ cm⁻³. Yet, in other aspects, the n-carrier dopant is present in the composition at a concentration of less than about 1×10¹⁴ cm⁻³, for example, about 5×10¹³ cm⁻³, or about 1×10¹³ cm⁻³.

In still further aspects, composition exhibits room temperature Hall mobility from about 130 cm²/V·s to about 165 cm²/V·s, including exemplary values of about 135 cm²/V·s, about 140 cm²/V·s, about 145 cm²/V·s, about 150 cm²/V·s, about 155 cm²/V·s, and about 160 cm²/V·s

In still further aspects, the composition is present as a substantially smooth thin film with much suppressed 3D surface structures formation. Such structures are known to appear on the surface of the films grown without Al presence. In yet still further aspects, the thin film has a thickness greater than about 2 μm, greater than about 3 μm, greater than about 4 μm, greater than about 5 μm, greater than about 6 μm, greater than about 7 μm, greater than about 8 μm, greater than about 9 μm, greater than about 10 μm, greater than about 15 μm, greater than about 20 μm, greater than about 50 μm, greater than about 80 μm, or greater than about 100 μm. In yet still further aspects, the thin film can have a thickness of less than about 100 μm, less than about 80 μm, less than about 50 μm, less than about 20 μm, less than about 15 μm, less than about 10 μm, less than about 9 μm, less than about 8 μm, less than about 7 μm, less than about 6 μm, less than about 5 μm, or less than about 4 μm. In yet still further aspects, the thin film thickness can be anywhere between greater than about 2 μm to about 500 μm, including exemplary values of about 5 μm, about 10 μm, about 20 μm, about 30 μm, about 40 μm, about 50 μm, about 60 μm, about 70 μm, about 80 μm, about 90 μm, about 100 μm, about 125 μm, about 150 μm, about 175 μm, about 200 μm, about 225 μm, about 250 μm, about 275 μm, about 300 μm, about 325 μm, about 350 μm, about 375 μm, about 400 μm, about 425 μm, about 450 μm, and about 475 μm.

Also disclosed herein are methods of making any of the compositions disclosed herein. For example, also disclosed herein are methods comprising exposing a β-Ga₂O₃-based substrate to an aluminum precursor, a gallium precursor, and/or oxygen precursor at a first temperature and a first pressure. Still, further methods comprise growing a β-(AlₓGa₁₋ₓ)₂O₃ thin film, wherein an x value is x value is less than about 5%. In still further aspects, the film is grown at a growth rate greater than about 3 μm/h or greater than about 10 μm/h. In such aspects, the film composition can be any composition as disclosed above. In yet further aspects, the growth rate can be greater than about 3 μm/h, greater than about 5 μm/h, greater than about 10 μm/h, or greater than about 20 μm/h. In yet still further aspects, the growth rate can be greater than about 3 μm/h to about 100 μm/h, including exemplary values of about 3.1 μm/h, about 3.5 μm/h, about 4 μm/h, about 5 μm/h, about 6 μm/h, about 7 μm/h, about 8 μm/h, about 9 μm/h, about 10 μm/h, about 20 μm/h, about 30 μm/h, about 40 μm/h, about 50 μm/h, about 60 μm/h, about 70 μm/h, about 80 μm/h, and about 90 μm/h.

In still further aspects, the film can be grown on a substrate. In such aspects, the β-Ga₂O₃-based substrate has a (010) orientation or other orientations such as (−201), (100), (001), (110).

In some examples, the methods can comprise metal-organic chemical vapor deposition (MOCVD), molecular-beam epitaxy (MBE), hydride vapor phase epitaxy (HVPE), pulsed laser deposition (PLD), low-pressure chemical vapor deposition (LPCVD), or a combination thereof. In some examples, the methods comprise metal-organic chemical vapor deposition (MOCVD).

It is understood that any known in the art precursors suitable for the desired applications can be used. In certain aspects, the gallium precursor comprises trimethylgallium (TMGa), triethylgallium (TEGa), or a combination thereof. In other aspects, the aluminum precursor comprises trimethylaluminum (TMAI), triethylaluminium (TEAI), or a combination thereof.

In some aspects, the aluminum precursor, the gallium precursors, the oxygen precursor, or a combination thereof are independently provided with a carrier gas. In such aspects, the carrier gas can comprise argon, helium, N₂, and the like, or combinations thereof.

In some examples, the gallium precursor and/or aluminum precursor and/or oxygen precursor is provided at a flow rate of about 1 umole/minute or more, about 2 μmol/min or more, about 3 μmol/min or more, about 4 μmol/min or more, about 5 μmol/min or more, about 6 μmol/min or more, about 7 μmol/min or more, about 8 μmol/min or more, about 9 μmol/min or more, about 10 μmol/min or more, about 15 μmol/min or more, about 20 μmol/min or more, about 25 μmol/min or more, about 30 μmol/min or more, about 35 μmol/min or more, about 40 μmol/min or more, about 45 μmol/min or more, about 50 μmol/min or more, about 55 μmol/min or more, about 60 μmol/min or more, about 65 μmol/min or more, about 70 μmol/min or more, about 75 μmol/min or more, about 80 μmol/min or more, about 85 μmol/min or more, about 90 μmol/min or more, about 95 μmol/min or more, about 100 μmol/min or more, about 105 μmol/min or more, about 110 μmol/min or more, about 115 μmol/min or more, about 120 μmol/min or more, about 125 μmol/min or more, about 130 μmol/min or more, about 135 μmol/min or more, about 140 μmol/min or more, about 145 μmol/min or more, about 150 μmol/min or more, about 155 μmol/min or more, about 160 μmol/min or more, about 165 μmol/min or more, about 170 μmol/min or more, about 175 μmol/min or more, about 180 μmol/min or more, about 185 μmol/min or more, about 190 μmol/min or more, about 195 μmol/min or more, about 200 μmol/min or more, about 205 μmol/min or more, about 210 μmol/min or more, about 215 μmol/min or more, about 220 μmol/min or more, about 225 μmol/min or more, about 230 μmol/min or more, about 235 μmol/min or more, about 240 μmol/min or more, or about 245 μmol/min or more.

In some examples, the gallium precursor and/or aluminum precursor and/or oxygen precursor is provided at a flow rate of about 250 pmole/minute or less about 245 μmol/min or less, about 240 μmol/min or less, about 235 μmol/min or less, about 230 μmol/min or less, about 225 μmol/min or less, about 220 mol/min or less, about 215 μmol/min or less, about 210 μmol/min or less, about 205 μmol/min or less, about 200 μmol/min or less, about 195 μmol/min or less, about 190 μmol/min or less, about 185 μmol/min or less, about 180 μmol/min or less, about 175 μmol/min or less, about 170 μmol/min or less, about 165 μmol/min or less, about 160 μmol/min or less, about 155 μmol/min or less, about 150 μmol/min or less, about 145 μmol/min or less, about 140 μmol/min or less, about 135 μmol/min or less, about 130 μmol/min or less, about 125 μmol/min or less, about 120 μmol/min or less, about 115 μmol/min or less, about 110 μmol/min or less, about 105 μmol/min or less, about 100 μmol/min or less, about 95 μmol/min or less, about 90 μmol/min or less, about 85 μmol/min or less, about 80 μmol/min or less, about 75 μmol/min or less, about 70 μmol/min or less, about 65 μmol/min or less, about 60 μmol/min or less, about 55 μmol/min or less, about 50 μmol/min or less, about 45 μmol/min or less, about 40 μmol/min or less, about 35 μmol/min or less, about 30 μmol/min or less, about 25 μmol/min or less, about 20 μmol/min or less, about 15 μmol/min or less, about 10 μmol/min or less, about 9 μmol/min or less, about 8 μmol/min or less, about 7 μmol/min or less, about 6 μmol/min or less, about 5 μmol/min or less, about 4 μmol/min or less, about 3 μmol/min or less, or about 2 μmol/min or less.

It is understood that the gallium precursor can be provided at a flow rate that is the same or different from the flow rate of the aluminum precursor. Yet, in other aspects, the gallium precursor can be provided at the flow rate that is the same or different from the flow rate of the oxygen precursor. Yet, in still further aspects, the aluminum precursor can be provided at a flow rate that is the same or different from the flow rate of the oxygen precursor.

In some examples, the first temperature is from about 650° C. to about 1,000° C., including exemplary values of about 675° C., about 700° C., about 725° C., about 750° C., about 775° C., about 800° C., about 825° C., about 850° C., about 875° C., about 900° C., about 925° C., about 950° C., and about 975° C.

In yet still further aspects, the first pressure is from about 5 torr to about 600 torr, including exemplary values of about 10 torr, about 20 torr, about 30 torr, about 40 torr, about 50 torr, about 60 torr, about 70 torr, about 80 torr, about 90 torr, about 100 torr, about 125 torr, about 150 torr, about 175 torr, about 200 torr, about 225 torr, about 250 torr, about 275 torr, about 300 torr, about 325 torr, about 350 torr, about 375 torr, about 400 torr, about 425 torr, about 450 torr, about 475 torr, about 500 torr, about 525 torr, about 550 torr, and about 575 torr.

In still further aspects, the concentration of the n-carrier dopant can be tunable. In such aspects, the concentration can be tuned by exposing the film to various flows of the n-carrier dopant depending on the desired application.

The flow rate of each precursor, the first temperature, the first pressure or a combination thereof can independently be selected in view of a variety of factors. For example, the methods can further comprise controlling the flow rate of each precursor, the temperature, pressure or a combination thereof to thereby control the growth rate of the film. In such exemplary and unlimiting aspects, the methods can comprise a processing unit that can independently control each variable to arrive at the desired composition.

Also disclosed herein are compositions made by any of the methods disclosed herein.

Also disclosed herein are devices comprising any of the compositions disclosed herein. For example, the device can comprise a vertical Schottky barrier diode, PN heterojunction power diodes, or a combination thereof. In yet still further aspects, the composition is a substrate, a drift layer or a combination thereof. In still further aspects, when both substrate and the drift layers are present, the drift layer and the substrate are lattice matched or with small lattice mismatch.

In some examples, the device comprises an optical device, an electronic device, an optoelectronic device, or a combination thereof.

Also disclosed herein are methods of use of any of the compositions disclosed herein.

A number of embodiments of the invention have been described. Nevertheless, it will be understood that various modifications may be made without departing from the spirit and scope of the invention. Accordingly, other embodiments are within the scope of the following claims.

The examples below are intended to further illustrate certain aspects of the devices and methods described herein and are not intended to limit the scope of the claims.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention that are apparent to one skilled in the art.

Efforts have been made to ensure accuracy with respect to numbers (e.g., amounts, temperature, etc.), but some errors and deviations should be accounted for.

Unless indicated otherwise, parts are parts by weight, the temperature is in °C. or is at ambient temperature, and pressure is at or near atmospheric. There are numerous variations and combinations of measurement conditions, e.g., component concentrations, temperatures, pressures and other measurement ranges and conditions that can be used to optimize the described process.

Due to its promising properties, including a large energy bandgap (4.8 eV), controllable n-type doping, and a high predicted breakdown field strength (˜8 MV/cm), β-Ga₂O₃ has been considered as a promising semiconductor material for the development of the next generation high power electronic devices. Despite the technology still being in its early stage of development, the use of bulk and epitaxial thin films in fabricating β-Ga₂O₃-based devices has made a significant progress, including lateral and vertical field effect transistors and Schottky barrier diodes (SBDs) with high breakdown voltage exceeding 2.8 kV. Vertical fin-shaped channel metal-insulator-semiconductor (MIS) field effect transistors (FinFETs) are demonstrated with more than 2 kV of breakdown voltage (BV). SBDs with a similar vertical fin structure are reported with a breakdown voltage of 2.89 kV with Baliga's figure-of-merit (BFOM) of 0.80 GW/cm² (BV²/R_{on,sp}). The performance of the β-Ga₂O₃ power devices, however, is still much below the predicted material's limit of β-Ga₂O₃. Several methods, including implanted edge termination, field plates, p-NiOₓ rings, fin structures, and high-k oxide field plates are considered to improve the BV of vertical-GazOs SBDs, but still lagging behind the conventional GaN and SiC-based SBDs. One approach to enhance the device breakdown limit can be the bandgap engineering of β-Ga₂O₃ by alloying with Al₂O₃, which can extend the accessible bandgap of β-(AlₓGa₁₋ₓ)₂O₃ alloy up to 7.51 eV. Due to its higher bandgap energy as compared to β-Ga₂O₃, β-(AlₓGa₁₋ₓ)₂O₃ alloy can serve as a promising candidate for the future development of high-power electronic devices with even higher critical field strength. While vertical SBDs have been demonstrated using β-Ga₂O₃ with limited BV (<3 KV), no studies on the development of vertical SBDs fabrication using thick β-(AlₓGa₁₋ₓ)₂O₃ films have been reported till date due to the limitation of thick film growths of β-(AlₓGa₁₋ₓ)₂O₃ films with controllable n-type doping.

For the application of high-performance power electronics with high reverse breakdown voltage, a thick drift layer with low controllable doping is needed to block large reverse-biased voltage. Due to its unavailability of single crystal native substrates, the epitaxial growth of β-(AlₓGa₁₋ₓ)₂O₃ thin films is mostly demonstrated on B-GazOs substrates, which limits the epitaxial growth of thick β-(AlₓGa₁₋ₓ)₂O₃ film due to the lattice mismatch. Also, the ground state crystal structures of thermally stable monoclinic β-Ga₂O₃ (space group C2/m) and corundum α-Al₂O₃ (space group R3c) are different. Higher Al incorporation in β-(AlₓGa₁₋ₓ)₂O₃ leads to a larger lattice mismatch between substrate and epi-film, resulting in lower critical thickness. In addition, the lower critical thickness of high Al composition β-(AlₓGa₁₋ₓ)₂O₃ film also limits the development of a thick drift layer to fabricate high voltage vertical devices using β-(AlₓGa₁₋ₓ)₂O₃. In order to develop high-performance vertical switching devices with higher breakdown voltage, a lightly doped thick drift layer with smooth surface morphologies is required.

Halide vapor phase epitaxy (HVPE) is an existing growth method that has demonstrated the growth of thick β-Ga₂O₃ with a relatively fast growth rate (>5 μm/hr) on (001) Ga₂O₃ substrates. However, this method produces films with rough surfaces that require chemo-mechanical polishing (CMP) process prior device fabrication, which not only increases cost but also introduces potential contaminants/defects on the polished surface. Therefore, a scalable growth method that can produce high-quality β-Ga₂O₃ with controllable doping in a wide range, fast enough growth rate, and smooth surface morphology is required.

The typical growth rate of MOCVD β-Ga₂O₃ ranges between 0.2-1.0 μm/hr, using triethylgallium (TEGa) as the Ga precursor. However, as the growth rate increases or with a relatively long growth time (>2 hr), the resulting β-Ga₂O₃ films have significant surface roughness. Thus, new methods to produce high-quality thick β-Ga₂O₃ films substantially free of surface roughness via MOCVD are still lacking.

In this disclosure, a method to develop thick β-(AlₓGa₁₋ₓ)₂O₃ films with very low Al composition (<5%), fast growth rate (>3 μm/hr), and controllable n-type doping via MOCVD is proposed. TMGa is used as a Ga precursor. In this method, the low Al molar flow rate provides Al adatoms on the growth surface and thus promotes more uniform nucleation sites. The associated advantages of the disclosed method include: (1) fast MOCVD growth rate of phase pure β-(AlₓGa₁₋ₓ)₂O₃ films with low Al composition and a substantially smooth surface morphology; (2) a higher bandgap of β-(AlₓGa₁₋ₓ)₂O₃ as compared to β-Ga₂O₃, resulting in the increased critical field strength of the film; and (3) controllable n-type doping with similar electron transport properties as β-Ga₂O₃.

For the MOCVD growth of β-(AlₓGa₁₋ₓ)₂O₃ films, either trimethylaluminum (TMAI) or triethylaluminium (TEAl) can be used as an Al precursor and pure O₂ can be used as an O precursor. Argon (Ar) or N₂ can be used as the carrier gas. The typical growth temperature can be varied between 650-1,000° C. and the typical chamber pressure can be varied between 5 and 600 torr. Phase pure β-(AlₓGa₁₋ₓ)₂O₃ thin films with Al composition up to x<5% can be grown by a systematical tuning of a ratio of VI/III elements, temperature, and chamber pressure. Si donor can be used as an effective n-type carrier in the MOCVD grown β-(AlₓGa₁₋ₓ)₂O₃ films.

### Example 1

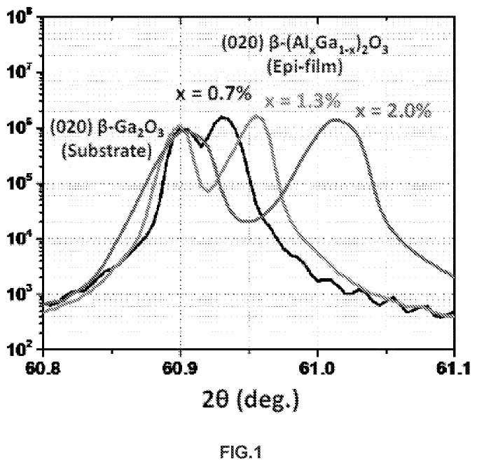

FIG. 1 shows the XRD ω-2θ scan spectra for a 3 μm thick (010) β-(AlₓGa₁₋ₓ)₂O₃ thin films grown at a temperature of 950° C. and pressure of 60 Torr. The (020) β-Ga₂O₃ peak corresponds to the signal from the (010) β-Ga₂O₃ substrates, The XRD peaks for (020) β-(AlₓGa₁₋ₓ)₂O₃ shift as the Al composition x increases from 0.7% to 2.0%. The strong peak intensities of the β-(AlₓGa₁₋ₓ)₂O₃ layers with narrow full width at half maximum (FWHMs) of the rocking curve indicate the high crystalline quality of the (020) β-(AlₓGa₁₋ₓ)₂O₃ grown on top of (010) β-Ga₂O₃ substrates. This is the first-time demonstration of MOCVD growth of such thick β-(AlₓGa₁₋ₓ)₂O₃ layers grown with a relatively fast growth rate (3.0 μm/hr).

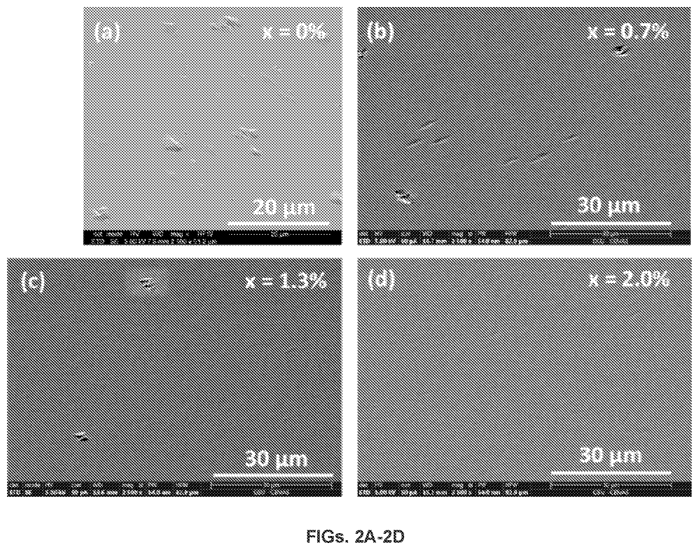

In addition to relatively higher bandgap energies of β-(AlₓGa₁₋ₓ)₂O₃ layer as compared to β-Ga₂O₃, the incorporation of Al adatoms on the growth surface also leads to the step-flow growth with surface homogeneity, which is essential to develop high-performance devices. The surface morphologies of the β-(AlₓGa₁₋ₓ)₂O₃ films are investigated by scanning electron microscopy (SEM) imaging. FIGS. 2A-2D show the surface SEM images of β-(AlₓGa₁₋ₓ)₂O₃ films grown with Al compositions from 0-2.0%. In the case of the β-Ga₂O₃ film (Al composition=0%), with a relatively fast growth rate, the Ga adatoms, in the absence of energetically favorable nucleation sites, attach to other Ga adatoms and nucleate a new island, resulting in nonuniform Ga adatom distribution with roughening of the surface with bumps like structures, as observed in FIG. 2A. By incorporating low Al compositions, for example, in the case of 0.7% of Al composition in the β-(AlₓGa₁₋ₓ)₂O₃ layer, the uniformity of Ga and Al distribution is significantly enhanced, and the surface morphology evolves from three-dimensional surface roughness to progressive smoothness, as shown in FIG. 2B. With the increase of Al molar flow rates, Al adatoms provide more distributed nucleation sites, which suppress the local 3D island growth modes and enhance the uniformity and mobility of adatoms on growth surface with less bumps like structure formation (FIGS. 2C-2D).

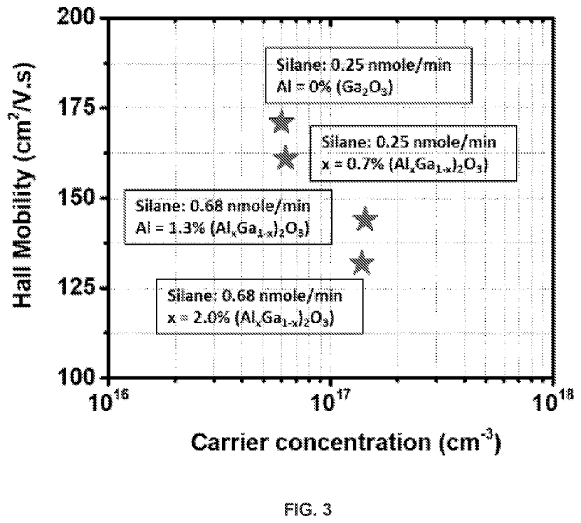

The electrical properties of these thick β-(AlₓGa₁₋ₓ)₂O₃ layers are also investigated by Hall measurement. FIG. 3 shows the room temperature Hall mobility of β-Ga₂O₃ and β-(AlₓGa₁₋ₓ)₂O₃ films with different Al compositions (x=0-2.0%) as a function of carrier concentration for two different silane flow rates (0.25 and 0.68 nmol/min). With the increase of carrier concentrations, the electron mobility reduces due to increased ionized impurity scattering. Excellent mobility of β-(AlₓGa₁₋ₓ)₂O₃ films ranging between 132-161 cm²/V·s with tunable carrier concentrations (6×10¹⁶−1.4×10¹⁷ cm⁻³) are achieved for different Al compositions, which are comparable to those of β-Ga₂O₃ films, indicating a great potential in developing thick drift β-(AlₓGa₁₋ₓ)₂O₃ layers with lower carrier concentration and smooth surface morphologies for fabricating high power vertical devices.

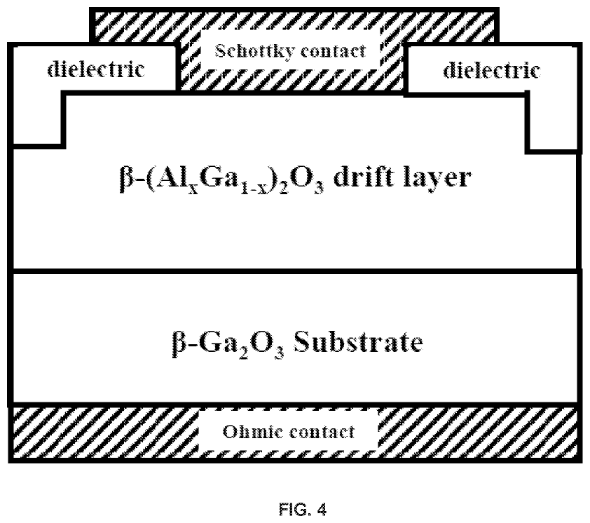

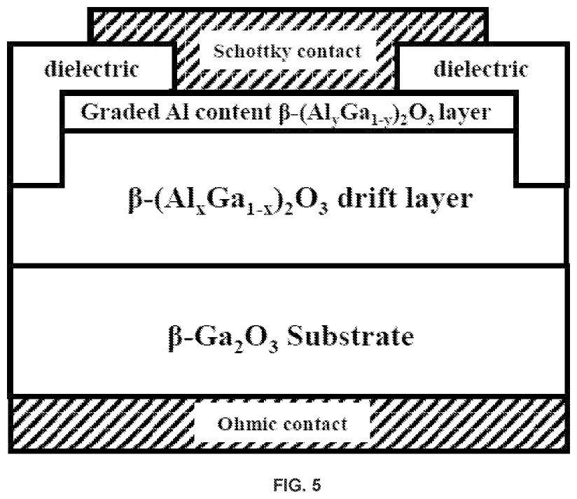

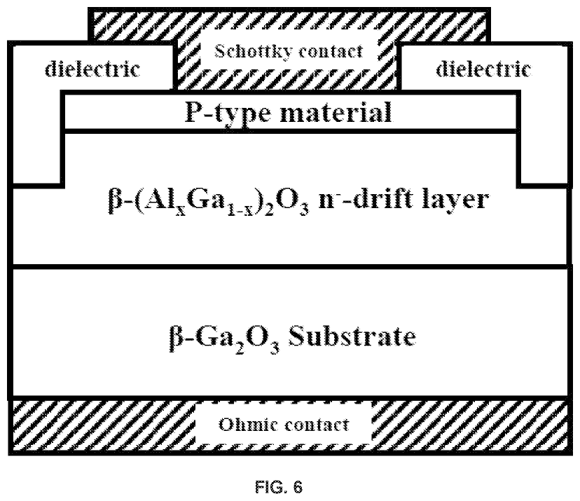

Align with this idea, vertical Schottky barrier diodes with/without using graded Al content β-(AlₓGa₁₋ₓ)₂O₃ layers can be developed based on β-(AlₓGa₁₋ₓ)₂O₃ films grown on β-Ga₂O₃ substrates as shown in the schematics in FIGS. 4 and 5, respectively. In addition, β-(AlₓGa₁₋ₓ)₂O₃-based PN heterojunction power diodes, as illustrated in FIG. 6, can be fabricated with increased power figure-of-merits (P-FOM) using thick low-Al content β-(AlₓGa₁₋ₓ)₂O₃ drift layer in accordance with the present invention. Such a thick β-(AlₓGa₁₋ₓ)₂O₃ drift layer with excellent electron mobility and low carrier concentrations will increase device breakdown limits for high-power operations.

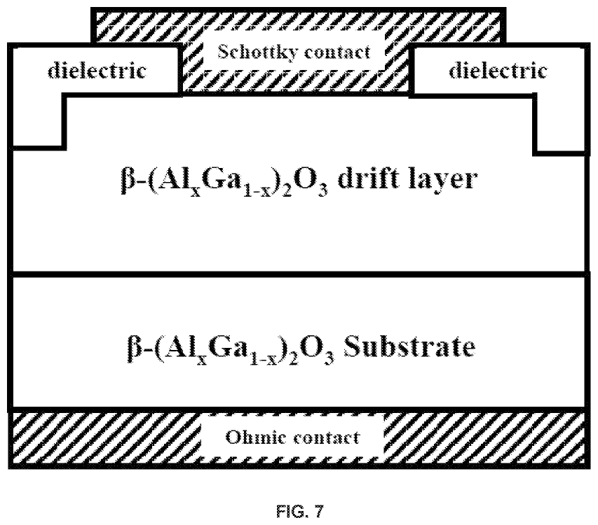

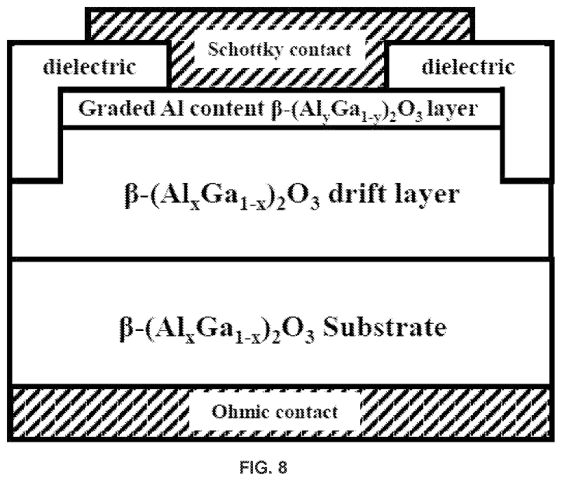

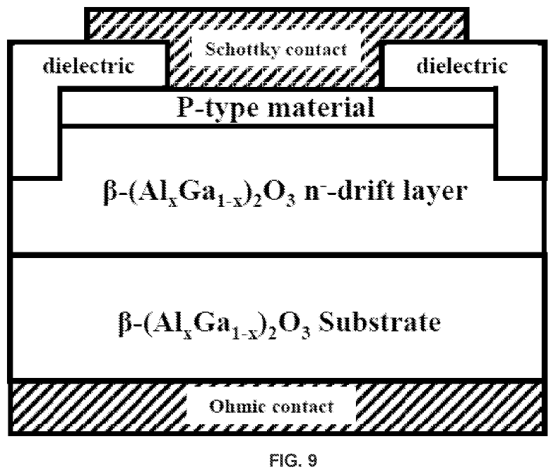

All the above proposed structures can be grown on lattice-matched (AlₓGa₁₋ₓ)₂O₃ substrates with the same Al composition of the drift layer. This will allow the growth of lattice-matched epi-layer without any strain. FIGS. 7-9 illustrate the schematics of these structures.

In summary, this invention on the MOCVD epitaxial development of high quality, thick and low Al content β-(AlₓGa₁₋ₓ)₂O₃ drift layer grown with fast growth rates and controllable doping will provide a new route to develop vertical power devices based on β-(AlₓGa₁₋ₓ)₂O₃/β-Ga₂O₃ heterostructures or β-(AlₓGa₁₋ₓ)₂O₃/β-(AlₓGa₁₋ₓ)₂O₃. The drift layer growth rate potentially can exceed 10 μm/hr, and the total drift layer thickness can reach 100 μm. Breakdown voltage for these devices can reach above 20 KV.

### EXEMPLARY ASPECTS

Example 1. A composition comprising a β-(AlₓGa₁₋ₓ)₂O₃, having an x value of less than about 5% and comprising at least one n-carrier dopant.

Example 2. The composition of any examples herein, particularly example 1, wherein the at least one n-carrier dopant comprises Si.

Example 3. The composition of any examples herein, particularly example 1 or 2, wherein a concentration of the n-carrier dopant is about 1×10¹⁴ cm⁻³ to about 5×10¹⁷ cm⁻³.

Example 4. The composition of any examples herein, particularly examples 1-3, wherein the composition exhibits room temperature Hall mobility from about 130 cm²/V·s to about 165 cm²/V·s.

Example 5. The composition of any examples herein, particularly examples 1-4, wherein the composition is present as a substantially smooth thin film.

Example 6. The composition of any examples herein, particularly example 5, wherein the thin film has a thickness greater than about 2 μm.

Example 7. The composition of any examples herein, particularly examples 5 or 6, wherein the thin film has a thickness greater than about 100 μm.

Example 8. A method of forming an Al-Ga-containing film comprising: (a) exposing a β-Ga₂O₃-based substrate to an aluminum precursor, a gallium precursor, and/or oxygen precursor at a first temperature and a first pressure; and (b) growing a β-(AlₓGa₁₋ₓ)₂O₃ thin film, wherein an x value is less than about 5%, at a growth rate greater than about 3 μm/h.

Example 9. The method of any examples herein, particularly example 8, wherein the growth rate is greater than about 10 μm/h.

Example 10. The method of any examples herein, particularly example 8 or 9, wherein the β-(AlₓGa₁₋ₓ)₂O₃ thin film has a thickness greater than about 2 μm.

Example 11. The method of any examples herein, particularly examples 8-10, wherein the β-(AlₓGa₁₋ₓ)₂O₃ thin film has a thickness greater than about 100 μm.

Example 12. The method of any examples herein, particularly examples 8-11, wherein the β-Ga₂O₃-based substrate has (010) orientation.

Example 13. The method of any examples herein, particularly examples 8-12, wherein the method of forming the Al-Ga-containing film comprises metal-organic chemical vapor deposition (MOCVD), molecular-beam epitaxy (MBE), hydride vapor phase epitaxy (HVPE), pulsed laser deposition (PLD), low-pressure chemical vapor deposition (LPCVD), or a combination thereof.

Example 14. The method of any examples herein, particularly examples 8-13, wherein the method comprises metal-organic chemical vapor deposition (MOCVD).

Example 15. The method of any examples herein, particularly examples 8-14, wherein the gallium precursor comprises trimethylgallium (TMGa), triethylgallium (TEGa), or a combination thereof.

Example 16. The method of any examples herein, particularly examples 8-15, wherein the aluminum precursor comprises trimethylaluminum (TMAI), triethylaluminium (TEAl), or a combination thereof.

Example 17. The method of any examples herein, particularly examples 8-16, wherein the first temperature is from about 650° C. to about 1,000° C.

Example 18. The method of any examples herein, particularly examples 8-17, wherein the first pressure is from about 5 torr to about 600 torr.

Example 19. The method of any examples herein, particularly examples 8-18, wherein the β-(AlxGa₁₋ₓ)₂O₃ thin film comprises at least one n-carrier dopant and wherein a concentration of the at least one n-dopant is tunable.

Example 20. The method of any examples herein, particularly example 19, wherein the at least one n-carrier dopant comprises Si.

Example 21. The method of any examples herein, particularly examples 8-20, wherein the film is substantially smooth.

Example 22. The method of any examples herein, particularly examples 19-21, wherein the film exhibits room temperature Hall mobility from about 130 cm²/V·s to about 165 cm²/V·s.

Example 23. The method of any examples herein, particularly examples 19-22, wherein the concentration of the at last one n-carrier dopant is about 1x1014-5x1017 cm-3.

Example 24. The method of any examples herein, particularly examples 8-23, wherein the method further comprises controlling a ratio of flow rate of gallium to aluminum precursor, the first temperature, the first pressure, or a combination thereof to thereby control the growth rate and the x value.

Example 25. The method of any examples herein, particularly examples 8-24, wherein the aluminum precursor, the gallium precursors, or a combination thereof are independently provided with a carrier gas.

Example 26. The method of any examples herein, particularly example 25, wherein the carrier gas comprises argon, helium, N₂, and the like, or combinations thereof.

Example 27. A composition made by the method of any examples herein, particularly examples 8-26.

Example 28. A device comprising the composition of any examples herein, particularly examples 1-7 or example 27.

Example 29. The device of example 28, wherein the device comprises a vertical Schottky barrier diode, PN heterojunction power diodes, or a combination thereof.

Example 30. The device of any examples herein, particularly example 28 or 29, wherein the composition is a substrate, a drift layer or a combination thereof.

Example 31. The device of any examples herein, particularly example 30, wherein the drift layer and the substrate are lattice matched.

Example 32. The device of any examples herein, particularly examples 28-31, wherein the device comprises an optical device, an electronic device, an optoelectronic device, or a combination thereof.

Example 33. A method of use of the composition of any examples herein, particularly examples 1-7 or example 27.

Other advantages which are obvious and which are inherent to the invention will be evident to one skilled in the art. It will be understood that certain features and sub-combinations are of utility and may be employed without reference to other features and sub-combinations. This is contemplated by and is within the scope of the claims.

Since many possible embodiments may be made of the invention without departing from the scope thereof, it is to be understood that all matter herein set forth or shown in the accompanying drawings is to be interpreted as illustrative and not in a limiting sense.

The methods of the appended claims are not limited in scope by the specific methods described herein, which are intended as illustrations of a few aspects of the claims, and any methods that are functionally equivalent are intended to fall within the scope of the claims. Various modifications of the methods, in addition to those shown and described herein, are intended to fall within the scope of the appended claims.

Further, while only certain representative method steps disclosed herein are specifically described, other combinations of the method steps also are intended to fall within the scope of the appended claims, even if not specifically recited. Thus, a combination of steps, elements, components, or constituents may be explicitly mentioned herein or less, however, other combinations of steps, elements, components, and constituents are included, even though not explicitly stated.

### REFERENCES

1. A. J. Green, J. Speck, G. Xing, P. Moens, F. Allerstam, K. Gumaelius, T. Neyer, A. Arias-Purdue, V. Mehrotra, A. Kuramata, K. Sasaki, S. Watanabe, K. Koshi, J. Blevins, O. Bierwagen, S. Krishnamoorthy, K. Leedy, A. R. Arehart, A. T. Neal, S. Mou, S. A. Ringel, A. Kumar, A. Sharma, K. Ghosh, U. Singisetti, W. Li, K. Chabak, K. Liddy, A. Islam, S. Rajan, S. Graham, S. Choi, Z. Cheng, and M. Higashiwaki, β-Gallium oxide power electronics. APL Mater. 2022, 10, 029201.
2. Z. Hu, H. Zhou, Q. Feng, J. Zhang, C. Zhang, K. Dang, Y. Cai, Z. Feng, Y. Gao, X. Kang, and Y. Hao, Field-Plated Lateral β-Ga2O3 Schottky Barrier Diode With High Reverse Blocking Voltage of More Than 3 kV and High DC Power Figure-of-Merit of 500 MW/cm2. IEEE Electron Device Lett. 2018, 39, 1564-1567.
3. W. Li, K. Nomoto, Z. Hu, T. Nakamura, D. Jena, H.G. Xing, Single and multi-fin normally-off Ga2O3 vertical transistors with a breakdown voltage over 2.6 kV. 2019 IEEE International Electron Devices Meeting (IEDM) 2019, pp. 12.4.1-12.4.4.
4. W. Li, K. Nomoto, Z. Hu, D. Jena, and H.G. Xing, Field-Plated Ga2O3 Trench Schottky Barrier Diodes With a BV2/Ron, sp of up to 0.95 GW/cm2. IEEE Electron Device Lett. 2020, 41, 107-110.
5. K. Konishi, K. Goto, H. Murakami, Y. Kumagai, A. Kuramata, S. Yamakoshi, and M. Higashiwaki, 1-kV vertical Ga2O3 field-plated Schottky barrier diodes. Appl. Phys. Lett. 2017, 110, 103506.
6. K. Sasaki, D. Wakimoto, Q. T. Thieu, Y. Koishikawa, A. Kuramata, M. Higashiwaki, and S. Yamakoshi, First Demonstration of Ga2O3 Trench MOS-Type Schottky Barrier Diodes. IEEE Electron Device Lett. 2017, 38, 783-785.
7. C.-H. Lin, Y. Yuda, M. H. Wong, M. Sato, N. Takekawa, K. Konishi, T. Watahiki, M. Yamamuka, H. Murakami, Y. Kumagai, and M. Higashiwaki, Vertical Ga2O3 Schottky Barrier Diodes With Guard Ring Formed by Nitrogen-lon Implantation. IEEE Electron Device Lett. 2019, 40, 1487-1490.
8. H. Zhou, Q. Yan, J. Zhang, Y. Lv, Z. Liu, Y. Zhang, K. Dang, P. Dong, Z. Feng, Q. Feng, J. Ning, C. Zhang, P. Ma, and Y. Hao, High-Performance Vertical β-Ga2O3 Schottky Barrier Diode With Implanted Edge Termination. IEEE Electron Device Lett. 2019, 40, 1788-1791.
9. Q. Yan, H. Gong, J. Zhang, J. Ye, H. Zhou, Z. Liu, S. Xu, C. Wang, Z. Hu, Q. Feng, J. Ning, C. Zhang, P. Ma, R. Zhang, and Y. Hao, β-Ga2O3 heterojunction barrier Schottky diode with reverse leakage current modulation and BV2/Ron, sp value of 0.93 GW/cm2. Appl. Phys. Lett. 2021, 118, 122102.
10. H. Peelaers, J. B. Varley, J. S. Speck, and C. G. Van de Walle, Structural and electronic properties of Ga2O3-Al2O3 alloys. Appl. Phys. Lett. 2018, 112, 242101.
11. S. Mu, M. Wang, H. Peelaers, C. G. Van de Walle, First-principles surface energies for monoclinic Ga2O3 and Al2O3 and consequences for cracking of (AlxGa1-x)2O3. APL Mater. 2020, 8, 091105.
12. A. F. M. A. U. Bhuiyan, Z. Feng, J. M. Johnson, H.-L. Huang, J. Sarker, M. Zhu, M. R. Karim, B. Mazumder, J. Hwang, and H. Zhao, Phase transformation in MOCVD growth of (AlxGa1-x)2O3 thin films. APL Mater. 2020, 8, 031104.
13. H. Murakami, K. Nomura, K. Goto, K. Sasaki, K. Kawara, Q. T. Thieu, R. Togashi, Y. Kumagai, M. Higashiwaki, A. Kuramata, S. Yamakoshi, B. Monemar, and A. Koukitu, Homoepitaxial growth of β-Ga2O3 layers by halide vapor phase epitaxy. Appl. Phys. Express 2015, 8, 015503.
14. R. Schewski, K. Lion, A. Fiedler, C. Wouters, A. Popp, S. V. Levchenko, T. Schulz, M. Schmidbauer, S. Bin Anooz, R. Grüneberg, Z. Galazka, G. Wagner, K. Irmscher, M. Scheffler, C. Draxl, M. Albrecht, Step-flow growth in homoepitaxy of β-Ga2O3 (100)—The influence of the miscut direction and faceting. APL Mater. 2019, 7, 022515.
15. S. Bin Anooz, R. Grüneberg, C. Wouters, R. Schewski, M. Albrecht, A. Fiedler, K. Irmscher, Z. Galazka, W. Miller, G. Wagner, J. Schwarzkopf, A. Popp, Step flow growth of β-Ga2O3 thin films on vicinal (100) β-Ga2O3 substrates grown by MOVPE. Appl. Phys. Lett. 2020, 116, 182106.
16. Z. Feng, A F M A. U. Bhuiyan, M. R. Karim, H. Zhao, MOCVD homoepitaxy of Si-doped (010) β-Ga2O3 thin films with superior transport properties. Appl. Phys. Lett. 2019, 114, 250601.
17. Z. Feng, A F M A. U. Bhuiyan, Z. Xia, W. Moore, Z. Chen, J. F. McGlone, D. R. Daughton, A. R. Arehart, S. A. Ringel, S. Rajan, H. Zhao, Probing Charge Transport and Background Doping in Metal-Organic Chemical Vapor Deposition-Grown (010) β-Ga2O3. Phys. Status Solidi RRL 2020, 14, 2000145.
18. L. Meng, Z. Feng, A F M A. U. Bhuiyan, H. Zhao, High-Mobility MOCVD β-Ga2O3 Epitaxy with Fast Growth Rate Using Trimethylgallium. Cryst. Growth Des. 2022, 22, 3896-3904.

What is claimed is:

1. A composition comprising a β-(AlₓGa₁₋ₓ)₂O₃, having an x value of less than about 5% and comprising at least one n-carrier dopant.

2. The composition of claim 1, wherein the at least one n-carrier dopant comprises Si.

3. The composition of claim 1 or 2, wherein a concentration of the at least one n-carrier dopant is about 1×10¹⁴ cm⁻³ to about 5×10¹⁷ cm⁻³.

4. The composition of any one of claims 1-3, wherein the composition exhibits room temperature Hall mobility from about 130 cm²/V·s to about 165 cm²/V·s.

5. The composition of any one of claims 1-4, wherein the composition is present as a substantially smooth thin film.

6. The composition of claim 5, wherein the thin film has a thickness greater than about 2 μm.

7. The composition of claim 5 or 6, wherein the thin film has a thickness greater than about 100 μm.

8. A method of forming an Al-Ga-containing film comprising:
a) exposing a β-Ga₂O₃-based substrate to an aluminum precursor, a gallium precursor, and/or oxygen precursor at a first temperature and a first pressure; and
b) growing a β-(AlₓGa₁₋ₓ)₂O₃ thin film, wherein an x value is less than about 5%, at a growth rate greater than about 3 μm/h.

9. The method of claim 8, wherein the growth rate is greater than about 10 μm/h.

10. The method of claim 8 or 9, wherein the β-(AlₓGa₁₋ₓ)₂O₃ thin film has a thickness greater than about 2 μm.

11. The method of any one of claims 8-10, wherein the β-(AlₓGa₁₋ₓ)₂O₃ thin film has a thickness greater than about 100 μm.

12. The method of any one of claims 8-11, wherein the β-Ga₂O₃-based substrate has (010) orientation.

13. The method of any one of claims 8-12, wherein the method of forming the Al-Ga-containing film comprises metal-organic chemical vapor deposition (MOCVD), molecular-beam epitaxy (MBE), hydride vapor phase epitaxy (HVPE), pulsed laser deposition (PLD), low-pressure chemical vapor deposition (LPCVD), or a combination thereof.

14. The method of any one of claims 8-13, wherein the method comprises metal-organic chemical vapor deposition (MOCVD).

15. The method of any one of claims 8-14, wherein the gallium precursor comprises trimethylgallium (TMGa), triethylgallium (TEGa), or a combination thereof.

16. The method of any one of claims 8-15, wherein the aluminum precursor comprises trimethylaluminum (TMAI), triethylaluminium (TEAI), or a combination thereof.

17. The method of any one of claims 8-16, wherein the first temperature is from about 650° C. to about 1,000° C.

18. The method of any one of claims 8-17, wherein the first pressure is from about 5 torr to about 600 torr.

19. The method of any one of claims 8-18, wherein the β-(AlₓGa₁₋ₓ)₂O₃ thin film comprises at least one n-carrier dopant and wherein a concentration of the at least one n-carrier dopant is tunable.

20. The method of claim 19, wherein the at least one n-carrier dopant comprises Si.

21. The method of any one of claims 8-20, wherein the film is substantially smooth.

22. The method of any one of claims 19-21, wherein the film exhibits room temperature Hall mobility from about 130 cm²/V·s to about 165 cm²/V·s.

23. The method of any one of claims 19-22, wherein a concentration of the at last one n-carrier dopant is about 1×10¹⁴-5×10¹⁷ cm⁻³.

24. The method of any one of claims 8-23, wherein the method further comprises controlling a ratio of flow rate of gallium to aluminum precursor, the first temperature, the first pressure, or a combination thereof to thereby control the growth rate and the x value.

25. The method of any one of claims 8-24, wherein the aluminum precursor, the gallium precursors, or a combination thereof are independently provided with a carrier gas.

26. The method of claim 25, wherein the carrier gas comprises argon, helium, N₂, or combinations thereof.

27. A composition made by the method of any one of claims 8-26.

28. A device comprising the composition of any one of claims 1-7 or claim 27.

29. The device of claim 28, wherein the device comprises a vertical Schottky barrier diode, PN heterojunction power diodes, or a combination thereof.

30. The device of claim 28 or 29, wherein the composition is a substrate, a drift layer or a combination thereof.

31. The device of claim 30, wherein the drift layer and the substrate are lattice matched.

32. The device of any one of claims 28-31, wherein the device comprises an optical device, an electronic device, an optoelectronic device, or a combination thereof.
